(19) United States
(12) Patent Application Publication
(10) Pub. No.: US 2025/0201795 A1
(43) Pub. Date: Jun. 19, 2025

(54) SYSTEM AND METHODS FOR A MODULAR HYBRID BONDING PACKAGE ARCHITECTURE

(71) Applicant: Samsung Electronics Co., Ltd., Suwon-si (KR)

(72) Inventors: Jin YANG, San Jose, CA (US); WooPoung KIM, San Jose, CA (US)

(21) Appl. No.: 18/810,393

(22) Filed: Aug. 20, 2024

Related U.S. Application Data
(60) Provisional application No. 63/612,353, filed on Dec. 19, 2023.

(51) Int. Cl. H01L 25/18; H01L 23/00; H01L 23/16; H10B 80/00

(52) U.S. Cl. CPC H01L 25/18; H01L 24/08; H01L 24/80; H01L 23/16; H01L 24/16; H01L 24/32; H01L 24/73; H01L 24/96; H01L 24/97; H01L 2224/08145; H01L 2224/16225; H01L 2224/32225; H01L 2224/73204; H01L 2224/80895; H01L 2224/80896; H01L 2224/96; H01L 2224/97; H01L 2924/1431; H01L 2924/1436; H10B 80/00

(57) ABSTRACT

Disclosed herein are methods, systems and devices including a first layer with at least one transistor, a second layer on a first side of the first layer, the second layer including a signal layer. A third layer may be on a second side of the first layer, the second side opposite the first side of the first layer, and the third layer may include a power layer. A stack may be coupled to the second layer, the stack including a first device row and a second device row. Each of the first device row and the second device row may include at least one device such as a computational device. The second device row may be mounted on the first device row, and the devices in the first device row may differ from the devices of the second device row.

### CROSS-REFERENCE TO RELATED APPLICATION

This application claims the priority benefit under 35 U.S.C. § 119 (e) of U.S. Provisional Patent Application Ser. No. 63/612,353 filed on Dec. 19, 2023, the disclosure of which is incorporated herein by reference in its entirety.

### TECHNICAL FIELD

The subject matter disclosed herein relates to microelectronics packaging and integrated circuits (IC) packaging. More particularly, the subject matter disclosed herein relates to a modular package architecture.

### BACKGROUND

Semiconductor devices may connect to additional devices and circuitry on different substrates. Forming connections between substrates can provide increased computation. However, forming connections between substrates can cause complications. Packaging describes the general method for connecting and integrating multiple computational components together in an integrated unit, and may involve multiple different types of integrated circuits on multiple substrates which may combine into a single unit. Packaging may also describe the method for which multiple computational components within a single unit are protected by the use of various techniques to provide thermal, physical and electrical protection. Background concepts discussed herein are for informational purposes only and are not intended to limit the present disclosure. Nor should the background or field described herein be intended to limit the disclosure herein to a particular use or concept.

### SUMMARY

An example embodiment provides a device including a first layer with at least one transistor, a second layer on a first side of the first layer, the second layer including a signal layer. A third layer may be on a second side of the first layer, the second side opposite the first side of the first layer, and the third layer may include a power layer. A stack may be coupled to the second layer, the stack including a first device row and a second device row. Each of the first device row and the second device row may include at least one device such as a computational device. The second device row may be mounted on the first device row, and the devices in the first device row may differ from the devices of the second device row. The first device row may include a processing device. The second device row may include a memory device. A memory device in the second row may be mounted on top of a processing device or another type of device. The memory device may be a dynamic random access memory device. The first device row may include at least one device. The first device row may include at least one device other than a memory device or a processing device. The stack may be mounted on the signal layer.

An example embodiment provides a system, the system including a substrate, the substrate including a logic layer. A first layer including a first device row may be over the substrate. A second layer including a second device row may be arranged over the first layer and the second device row may be coupled to the first device row. A third layer including a third device row may be arranged over the second layer, and the third device row may be coupled to the second device row. The first device row, the second device row, and the third device row may each include at least one device. The device composition of the first device row may differ from the second device row. The device composition of the third device row may be substantially the same as the second device row. The substrate may include a power layer and a signal layer, the power layer coupled to the logic layer, and the logic layer coupled to the signal layer. The power layer and the signal layer may be coupled to the first layer. The first device row may include a processing device. The second device row may include a memory device.

An example embodiment provides a method including forming a transistor layer including at least one transistor on the first side of a first substrate; forming a signal layer on the transistor layer, the signal layer communicatively coupled to the transistor layer; forming a power layer on a second side of the first substrate, the second side of the first substrate opposite the first side, the power layer electrically coupled to the transistor layer; bonding a first device row to the signal layer and bonding a second device row to the first device row. In some embodiments, bonding the first device row on the signal layer may include depositing a dielectric layer, patterning a via in the dielectric layer, and heating the first device row and the signal layer together to bond the first device row and the signal layer. In some embodiments, the device composition of the second device row may differ from the first device row. In some embodiments, a third device row may be bonded to the second device row, the third device row having the same device composition as the second device row. In some embodiments, forming the signal layer on the transistor layer includes forming a redistribution layer on the surface of the signal layer, and bonding the first device row to the signal layer includes depositing a first dielectric layer over the redistribution layer; patterning the first dielectric layer to expose an exposed portion of the redistribution layer; mounting conductive contacts of the first device row on exposed portions of the redistribution layer, and performing a thermal process to bond the exposed portion of the redistribution layer to the conductive contacts of the first device row.

### BRIEF DESCRIPTION OF THE DRAWING

In the following section, the aspects of the subject matter disclosed herein will be described with reference to exemplary embodiments illustrated in the figures, in which:

FIG. 1A depicts a cross-section view of an example embodiment of a packaging structure according to various embodiments of the subject matter disclosed herein;

FIG. 1B depicts an enlarged cross-section view of an example embodiment of a packaging structure according to various embodiments of the subject matter disclosed herein;

FIG. 2 depicts an enlarged cross-section view of an example embodiment of a packaging structure according to various embodiments of the subject matter disclosed herein;

FIG. 3 depicts a cross-section view of an example embodiment of a packaging structure assembly according to various embodiments of the subject matter disclosed herein;

FIG. 4A depicts a cross-section view of an example embodiment of a packaging structure assembly at a first time according to various embodiments of the subject matter disclosed herein;

FIG. 4B depicts a cross-section view of an example embodiment of a packaging structure assembly at a second time according to various embodiments of the subject matter disclosed herein;

FIG. 4C depicts a cross-section view of an example embodiment of a packaging structure assembly at a third time according to various embodiments of the subject matter disclosed herein;

FIG. 4D depicts a cross-section view of an example embodiment of a packaging structure assembly at a fourth time according to various embodiments of the subject matter disclosed herein;

FIG. 4E depicts a cross-section view of an example embodiment of a packaging structure assembly at a fifth time according to various embodiments of the subject matter disclosed herein;

FIG. 4F depicts a cross-section view of an example embodiment of a packaging structure assembly at a sixth time according to various embodiments of the subject matter disclosed herein;

FIG. 4G depicts a cross-section view of an example embodiment of a packaging structure assembly at a seventh time according to various embodiments of the subject matter disclosed herein;

FIG. 4H depicts a cross-section view of an example embodiment of a packaging structure assembly at an eight time according to various embodiments of the subject matter disclosed herein;

FIG. 4I depicts a cross-section view of an example embodiment of a packaging structure assembly at a ninth time according to various embodiments of the subject matter disclosed herein;

FIG. 4J depicts a cross-section view of an example embodiment of a packaging structure assembly at a tenth time according to various embodiments of the subject matter disclosed herein;

FIG. 4K depicts a cross-section view of an example embodiment of a packaging structure assembly at an eleventh time according to various embodiments of the subject matter disclosed herein;

FIG. 4L depicts a cross-section view of an example embodiment of a packaging structure assembly at a twelfth time according to various embodiments of the subject matter disclosed herein;

FIG. 5 depicts an example embodiment of a method of forming a package structure according to various embodiments of the subject matter disclosed herein;

FIG. 6A depicts a cross-section view of an example embodiment of a packaging structure assembly according to various embodiments of the subject matter disclosed herein; and

FIG. 6B depicts an enlarged cross-section view of an example embodiment of a packaging structure assembly according to various embodiments of the subject matter disclosed herein.

### DETAILED DESCRIPTION

In the following detailed description, numerous specific details are set forth in order to provide a thorough understanding of the disclosure. It will be understood, however, by those skilled in the art that the disclosed aspects may be practiced without these specific details. In other instances, well-known methods, procedures, components and circuits have not been described in detail to not obscure the subject matter disclosed herein.

Reference throughout this specification to “one embodiment” or “an embodiment” means that a particular feature, structure, or characteristic described in connection with the embodiment may be included in at least one embodiment disclosed herein. Thus, the appearances of the phrases “in one embodiment” or “in an embodiment” or “according to one embodiment” (or other phrases having similar import) in various places throughout this specification may not necessarily all be referring to the same embodiment. Furthermore, the particular features, structures or characteristics may be combined in any suitable manner in one or more embodiments. In this regard, as used herein, the word “exemplary” means “serving as an example, instance, or illustration.” Any embodiment described herein as “exemplary” is not to be construed as necessarily preferred or advantageous over other embodiments. Additionally, the particular features, structures, or characteristics may be combined in any suitable manner in one or more embodiments. Also, depending on the context of discussion herein, a singular term may include the corresponding plural forms and a plural term may include the corresponding singular form. Similarly, a hyphenated term (e.g., “two-dimensional,” “pre-determined,” etc.) may be occasionally interchangeably used with a corresponding non-hyphenated version (e.g., “two dimensional,” “predetermined, etc.), and a capitalized entry (e.g., “Integrated Chip,” “First Substrate,” “CMOS,” etc.) may be interchangeably used with a corresponding non-capitalized version (e.g., “integrated chip,” “first substrate,” “cmos,” etc.). Such occasional interchangeable uses shall not be considered inconsistent with each other.

Also, depending on the context of discussion herein, a singular term may include the corresponding plural forms and a plural term may include the corresponding singular form. It is further noted that various figures (including component diagrams) shown and discussed herein are for illustrative purpose only, and are not drawn to scale. For example, the dimensions of some of the elements may be exaggerated relative to other elements for clarity. Further, if considered appropriate, reference numerals have been repeated among the figures to indicate corresponding and/or analogous elements.

The terminology used herein is for the purpose of describing some example embodiments only and is not intended to be limiting of the claimed subject matter. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element or layer is referred to as being on, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items. As used herein, couple may refer to electrically coupling, communicatively coupling, physically coupling, and/or thermally coupling objects.

The terms “first,” “second,” etc., as used herein, are used as labels for nouns that they precede, and do not imply any type of ordering (e.g., spatial, temporal, logical, etc.) unless explicitly defined as such. Furthermore, the same reference numerals may be used across two or more figures to refer to parts, components, blocks, circuits, units, or modules having the same or similar functionality. Such usage is, however, for simplicity of illustration and ease of discussion only; it does not imply that the construction or architectural details of such components or units are the same across all embodiments or such commonly-referenced parts/modules are the only way to implement some of the example embodiments disclosed herein.

Unless otherwise defined, all terms (including technical and scientific terms) used herein have the same meaning as commonly understood by one of ordinary skill in the art to which this subject matter belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein substrates may refer to a variety of materials and structures, including wafers using silicon, wafers using silicon on an insulator (SOI) such as glass, wafers of other semiconductor materials such as germanium, as well as other semiconductor materials on an insulator. In some embodiments, a substrate may include an organic material. In some embodiments, the substrates may be referred to as wafers, dies, and chips alone or in combination. Bonding substrates may be thus known in some embodiments as die-to-die (D2D) bonding, wafer-to-wafer bonding (W2 W) or die-to-wafer bonding (D2 W). In some embodiments, the substrates may contain circuits such as integrated circuits including central processing units (CPUs), logic chips, memory such as static random-access memory (SRAM), dynamic random-access memory (DRAM), synchronous dynamic random-access memory (SDRAM), double data rate DRAM or DDR DRAM, application processors (AP), graphical processing units (GPUs), other forms of auxiliary processing units (xPU), Artificial intelligence (AI) chips, High bandwidth memory (HBM) interfaces, and other application-specific integrated circuits (ASIC). In some embodiments, a combination of circuits may be present on a substrate. In some embodiments, a substrate may include a packaged chip.

As used herein packaging refers to a process of forming interconnections between substrates. In some embodiments, the interconnections may be between direct surfaces and involve W2 W, D2D, and D2 W bonding. In other embodiments, techniques including wire bonding and other forms of indirect bonding may be performed alone or in combination with W2 W, D2D, and D2 W bonding. In some embodiments, circuits may be bonded directly facing each other, while in other embodiments a flip-chip bonding may be used. In some embodiments, interconnections may be made between substrates on a front or circuit side of the substrate. In other embodiments, interconnections may be made on a rear or back side of the substrate opposite from the circuit structure. In some embodiments, an interconnection may include through-silicon vias (TSVs) or other forms of through-chip vias where one or more substrates may be connected using a via extending through an interposer such as another substrate or chip. In some embodiments, an interconnection may be formed using connections on a surface of a substrate, such as a pad, and may use additional materials between the pads such as solder to form an interconnection.

As used herein, conductors may refer to a variety of conductive materials, including which materials may be used alone or in combination with other materials such as in the form of an alloy. In some embodiments the conductor is copper (Cu). In some embodiments, copper (Cu) may be in the form of Cu (II), Cu (III) or other forms of copper, alone or in combination with additional elements, including cobalt (Co) and ruthenium (Ru). Such a listing of elements is not intended to be exhaustive, and in other embodiments, any known other type of conductive material may be used.

As used herein dielectrics may refer to a variety of materials including various forms of silicon such as silicon oxides including SiO₂, silicon nitrides including SiN, silicon carbonitrides including SiCN. In some embodiments, dielectric materials may be referred to as electrically insulating materials, insulative regions, or as insulators. In some embodiments, the amount of insulation provided may be relative to another material which may be referred to as a conductive material or conductor.

As used herein, a chiplet may refer to an integrated circuit having a well-defined functionality, such as a microprocessor, a memory device, or other computational function; with a chiplet enabling a modular design with multiple chiplets able to be combined with a larger package, sharing a substrate or interposer to form a larger device. A core may refer to a single-unit of a multicore device where multiple devices form a larger device, with each device able to function independently to enable multiple streams of operations. In some embodiments, a core may take the form of a chiplet, or a chiplet may take the form of a core. However, in other embodiments, a chiplet may take the form of any other suitable integrated circuit. A device, a compute device, and a die may be used herein to refer to chiplet or vice versa.

Disclosed herein are various embodiments of devices, systems and methods related to packaging architecture to modularly create a stack logic and building block architecture using hybrid bonding. A stack logic and building block architecture may include a base chip providing logic, routing, and power delivery to a stack of memory. As used herein, a stack or may refer to some combination of processing, memory and supporting circuit architecture, for example, chiplets and dies containing individual elements, memory dies, supporting processing units, I/O circuitry, and other forms of integrated chips. As used herein, device composition may refer to which devices are used within a row, system or other object. A stack may also be referred to as a device stack, die stack or chiplet stack.

In some embodiments, a backside power delivery network (BSPDN) may be formed on the backside of a substrate, with a signal network formed on the front side of the same substrate. In some embodiments, the layer containing a BSPDN may be referred to as a power layer. In some embodiments, the BSPDN and signal network may be formed on separate substrates and transferred to the same substrate. The BSPDN and signal network may be separated by a transistor layer. The transistor layer may include a plurality of transistors. The transistors may provide different functions and take different forms, including a logic layer. The BSPDN and signal network may form a single monolithic structure on the same die in a semiconductor foundry process. A stacked module may be separately formed in a semiconductor foundry process, the same semiconductor foundry process, or may have multiple components formed in multiple semiconductor foundry processes and assembled in a packaging assembly process.

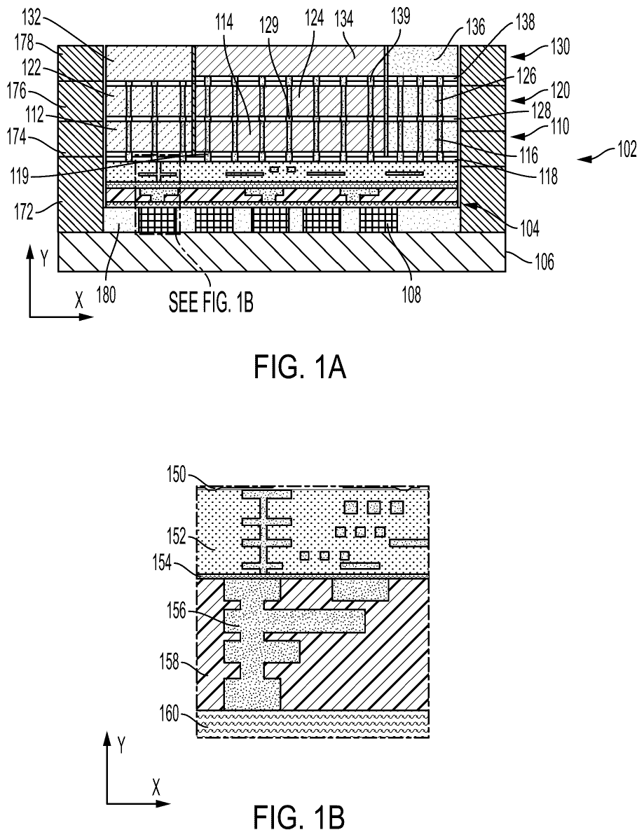

FIG. 1A depicts an exemplary embodiment of a package architecture 100 which integrates a base chip 104 using backside power delivery with a chiplet stack 102. In package architecture 100, the chiplet stack 102, which is composed of multiple layers of devices or chiplets, is coupled with a base chip 104 with power and signal layers and mounted on a supporting substrate 106 in a stack formation as shown in FIG. 1B. The devices in the chiplet stack 102 may include computing, processing, network, memory, other types of devices. In some embodiments, the base die may be a silicon die, while in other embodiments a variety of semiconductor materials may be used.

The chiplet stack 102 may include a plurality of layers, including a first stack layer 110, a second stack layer 120, and a third stack layer 130. Each of the first stack layer 110, the second stack layer 120, and the third stack layer 130 may include one or more devices. The number of stack layers, and the number of devices in each stack layer may vary. While in the exemplary embodiment of FIG. 1A and FIG. 1B, the first, second and third stack layers are shown to be identical, in other embodiments the number and/or the type of devices in at least one stack layer may differ from the number and/or type of devices in another stack layer.

The first stack layer 110 includes a first device 112, a second device 114, and a third device 116. The second stack layer 120 includes a fourth device 122, a fifth device 124, and a sixth device 126. The third stack layer 130 includes a seventh device 132, an eighth device 134, and a ninth device 136. The devices within each of the stack layers may comprise a chiplet, such as a die or chiplet, as well as supporting circuitry such as other forms of IC which may be also in the form of chiplets or devices. For example, a chiplet such as a processor, processing core, processing device, or memory die, for the chiplet stack 102 may be included within a stack layer, as well as power distribution, routing, and I/O chiplets. The devices used within each stack layer may be relatively thin, with a thickness of, for example, 20-30 microns, up to 50 microns. In some embodiments, the devices in each stack layer may be even thinner, although in some embodiments, the thickness may be larger or smaller.

In some embodiments, the first stack layer 110 may include a first supporting dielectric layer 174 which may form the sides of the first stack layer 110. The first supporting dielectric layer 174 may comprise a dielectric material, and may form a structural and thermal support as part of the first stack layer 110. In some embodiments, the second stack layer 120 may include a second supporting dielectric layer 176 which may form the sides of the second stack layer 120. The second supporting dielectric layer 176 may comprise a dielectric material, and may form a structural and thermal support as part of the second stack layer 120. In some embodiments, the third stack layer 130 may include a third supporting dielectric layer 178 which may form the sides of the third stack layer 130. The third supporting dielectric layer 178 may comprise a dielectric material, and may form a structural and thermal support as part of the third stack layer 130.

The chiplet stack 102 may include a plurality of bonding layers to connect the stack layers and provide mechanical, electrical, and thermodynamic connections between the layers. The bonding layers may include multiple materials, including a dielectric material, and may further include a metal material. In some embodiments, the bonding layers may include bonding between conductive materials at a surface layer, as well as bonding between dielectric materials on a surface layer. In some embodiments, the bonding process may be a hybrid bonding process in which both the dielectric and conductive regions are bonded together between layers. In some embodiments, dielectric regions may be bonded together using fusion bonding. In some embodiments, the hybrid bond may combine conductive regions at high temperature conditions, while dielectric portions may bond at temperatures closer to room temperature. In some embodiments, the material surrounding the thin chiplets/devices may include a dielectric layer with a thickness of for example, 20-30 microns, and may extend up to 50 microns, (same or similar thickness to chiplet/device) although in other embodiments, the dielectric layer may differ in size. In some embodiments, the thickness of the stack layers and the thickness of the bonding layers may be substantially the same, while in other embodiments, they may vary,

A first bonding layer 118 may form the base of the chiplet stack 102, with the first stack layer 110 held secure to the base chip 104 using the first bonding layer 118. The first bonding layer 118 may include a first set of conductive contacts 119 providing an interconnection between the base chip 104 and the devices of the first stack layer 110. In some embodiments, the first set of conductive contacts 119 may align with a TSV or other form of via through the first stack layer 110.

A second bonding layer 128 may form the base of the second stack layer 120, holding the second stack layer 120 in place and connected to the first stack layer 110. The second bonding layer 128 may include a second set of conductive contacts 129 providing an interconnection between the first stack layer 110 and the devices of the second stack layer 120. In some embodiments, the second set of conductive contacts 129 may align with a TSV or other form of via through the second stack layer 120.

A third bonding layer 138 may form the base of the third stack layer 130, holding the third stack layer 130 in place and connected to the second stack layer 120. The third bonding layer 138 may include a third set of conductive contacts 139 providing an interconnection between the devices of the second stack layer 120 and the devices of the third stack layer 130. In some embodiments, the third set of conductive contacts 139 may align with a TSV or other form of via through the third stack layer 130.

Additionally, the first bonding layer 118 couples the chiplet stack 102 to the base chip 104 at a redistribution layer 150. The redistribution layer 150 is coupled to a signal network layer 152, which is in turn coupled to a transistor layer 154. The redistribution layer 150 may include a series of pads, lines, traces, and other forms of connection forming the top surface of the base chip 104. The redistribution layer 150 allows for connections between the chiplet stack 102 and the base chip 104 to be spread out from where lines and vias may emerge on the surface of the signing section, allowing additional space for the connections to be formed, as well as providing additional space to prevent inadvertent connections.

The signal network layer 152 may comprise a network-on-a-chip (NOC), and may provide interconnections to transport signals to and from the chiplet stack 102. In some embodiments, the signal network layer 152 may provide packet routing. In some embodiments, the signal network layer 152 may comprise a plurality of layers, including multiple layers providing signal routing. In some embodiments, the signal network layer 152 may comprise a plurality of conductive channels within a dielectric material, and the plurality of conductive channels may be arranged in multiple layers, with the size of the conductive channels decreasing in distance from the transistor layer 154. In some embodiments, the signal network layer 152 may have a plurality of plurality of conductive channels and may include 15-20 signal layer including conductive channels. In some embodiments, the conductive channels may be a conductive material such as a metal, including copper. In some embodiments, the size of the conductive channels in a top layer of the signal network layer 152 may be increasing with size in distance from the transistor layer 154, while in other embodiments, the size of the conductive channels may be constant.

The transistor layer 154 separates the signal network layer 152 from a BSPDN layer 158 and includes a plurality of transistors. As used herein, the transistor layer 154 may be used to refer to both the layer containing the plurality transistors and the plurality of transistors. In some embodiments, the transistor layer 154 may act as the base logic for both the signal network layer 152 and the BSPDN layer 158. In other embodiments, the transistor layer 154 along with the signal network layer 152 and the BSPDN layer 158 provide the base logic for the chiplet stack 102. The BSPDN layer 158 provides a power delivery network for routing power supply lines 156 on the back side of the transistor layer 154 and may provide both power and reference voltages to transistors in transistor layer 154. The BSPDN layer 158 may include multiple different layers of power supply lines 156 routing power within an insulating material. In some embodiments the insulating material may include a dielectric material. In some embodiments, the BSPDN layer 158 may include 4 to 6) layers of the power supply lines 156. In some embodiments, the size of the power supply lines 156 may decrease as they approach the transistor layer 154. The power supply lines 156 may be comprised of conductive materials, including various forms of low resistive metals, such as copper, alternatively or in addition, the conductive materials may include various forms of other conductive materials, including doped carbon. A supporting base dielectric layer 172 may form the sides of the base chip 104. The supporting base dielectric layer 172 may be comprised of a dielectric material and may extend from the supporting substrate 106 to the first stack layer 110.

A dielectric layer 160 forms the bottom of the BSPDN layer 158 and in some embodiments, may include a via with a plug to couple the BSPDN layer 158 to the supporting substrate 106 with an interconnect 108. In some embodiments, a plurality of plugs and vias may be used to couple the BSPDN layer 158 to the supporting substrate 106. The interconnect 108 may include pads, bumps, microbumps, pillars, balls, and other forms such as controlled-collapse chip connection (C4) bumps, alone or in combination. As used herein, a C4 bump refers to a form of solder bumps placed on pads on a top surface of a substrate prior to flipping the substrate to form a flip-chip. In some embodiments, interconnect 108 may further include a dielectric material, which may include a material such as an adhesive, resin, or elastomer which may form a connection between the BSPDN layer 158 and the supporting substrate 106 in addition to a conductive connection. In some embodiments, the combination of a conductive connection and a dielectric connection may form a hybrid bond. The supporting substrate 106 may in turn connect to other devices and dies, and in some embodiments, may take the form of an interposer. In some embodiments, an underfill material 180 may be injected between the dielectric layer 160 and the supporting substrate 106. In some embodiments, the underfill material 180 may be a dielectric material, and may form a hybrid bond along one or more conductive connections in the interconnect 108.

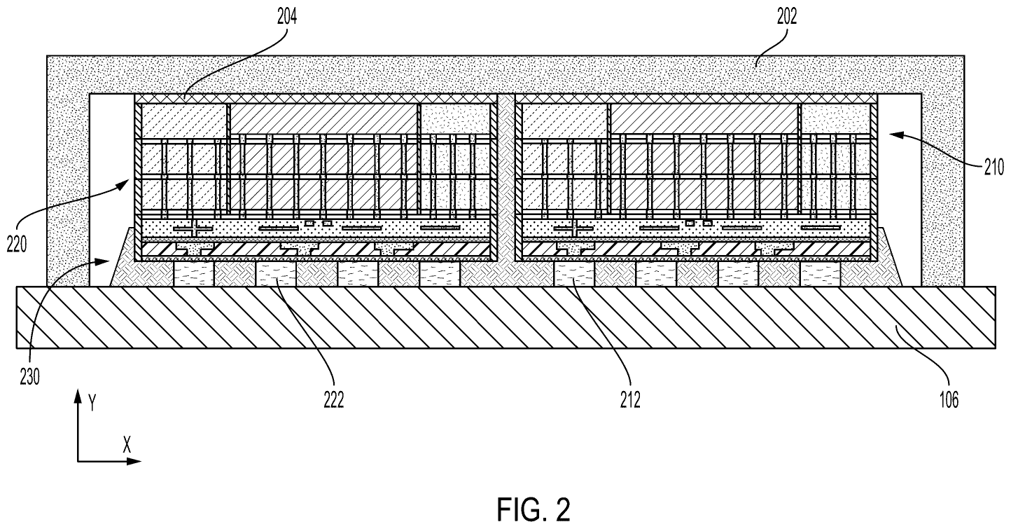

FIG. 2 depicts an example embodiment of an encapsulated structure 200 containing multiple device arrays integrated in one package. In FIG. 2, differing from FIG. 1A and FIG. 1B, multiple packages, including a first package 210 and a second package 220, may be provided for on the supporting substrate 106. The first package 210 and the second package 220 can take the form of any package disclosed herein, including the package architecture 100. The first package 210 and the second package 220 may be or assembled together, then the first package 210 may be connected to the supporting substrate 106 using a first interconnection 212 and the second package 220 may be connected to the supporting substrate 106 using a second interconnection 222. The first interconnection 212 and the second interconnection 222 may include pads, bumps, microbumps, pillars, balls, and other forms such as C4 bumps, alone or in combination. In some embodiments, the first interconnection 212 and the second interconnection 222 may further include one or more dielectric materials, such as an underfill material or any other suitable material.

In FIG. 2, an encapsulation structure 202 is formed over and encloses the first package 210 and the second package 220. The encapsulation structure 202 may be made, for example from a nickel-plated copper lid or heat slug or additive manufacturing. Additional layers of thermal interface material 204 may be used to bond the encapsulation structure 202 directly to the first package 210 and the second package 220 for thermal spreading purpose. In some embodiments, the encapsulation structure 202 may additionally seal the first package 210 and the second package 220 In some embodiments, the encapsulation structure 202 may partially or fully open, and a partially open form of the encapsulation structure 202 may, for example, allow airflow to transfer heat from the first package 210 and the second package 220. In some embodiments, the encapsulation structure 202 may provide for mechanical support for the first package 210 and the second package 220, and may provide protection against mechanical deformation, drop shock, etc. In some embodiments, an underfill material 230 may be injected between the first package 210, the second package 220 and the supporting substrate 106. In some embodiments, the underfill material 230 may be a dielectric material, and may be used for forming a dielectric bond. In some embodiments, a hybrid bond may be formed by a combination of a metallic bond and a dielectric bond, such as one or more of the first interconnection 212, the second interconnection 222, and the underfill material 230 along with other suitable materials.

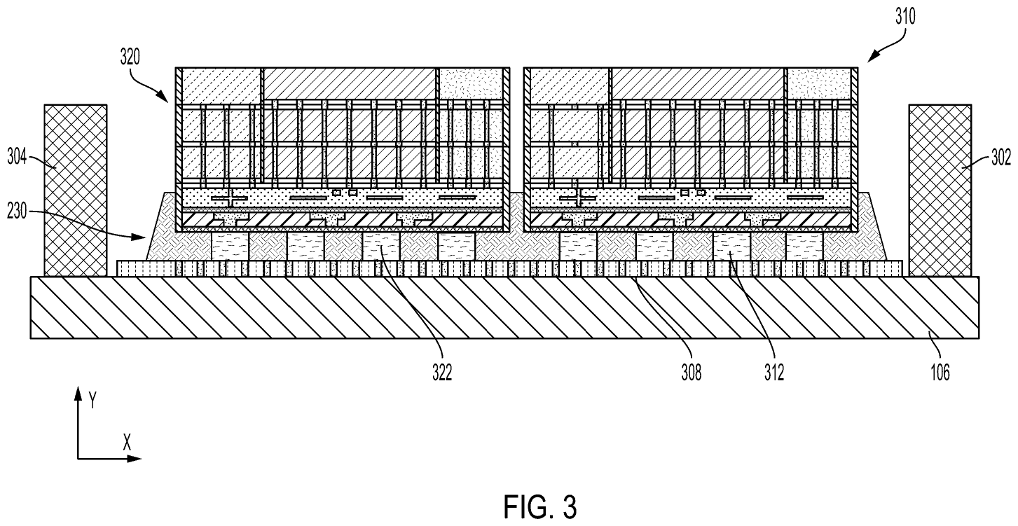

FIG. 3 depicts an example embodiment of a supported interposer structure 300. In FIG. 3, multiple packages, including a third package 310 and a fourth package 320, are provided for on the supporting substrate 106 via an interposer 308. The third package 310 and the fourth package 320 can take the form of any package disclosed herein, including the package architecture 100. The third package 310 and the fourth package 320 may be separately assembled, or assembled together, then the third package 310 may be connected to the interposer 308 using a third interconnection 312 and the fourth package 320 may be connected to the interposer 308 using a fourth interconnection 322. The interconnections may include pads, bumps, microbumps, pillars, balls, and other forms such as C4 bumps, alone or in combination. The interposer 308 may take the form of a substrate having additional interconnections, lines, and circuitry, which the third package 310 and the fourth package 320 are mounted thereon. Additionally, stiffeners, shown in the form of a first stiffener 302 and a second stiffener 304 may be provided on the supporting substrate 106 to provide additional mechanical support. In some embodiments, an underfill material 230 may be injected between the third package 310, the fourth package 320 and the supporting substrate 106.

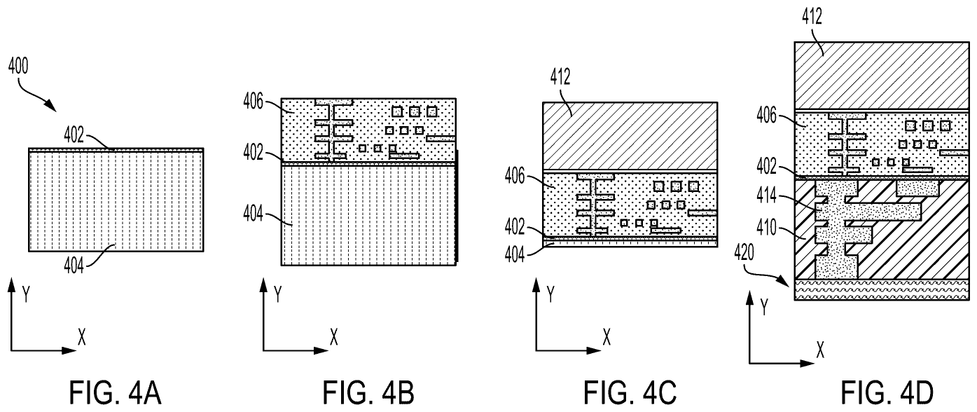

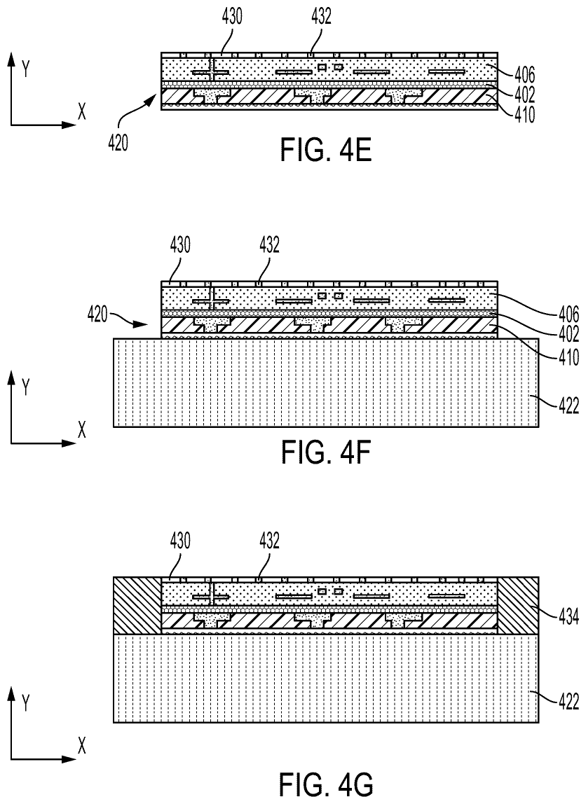

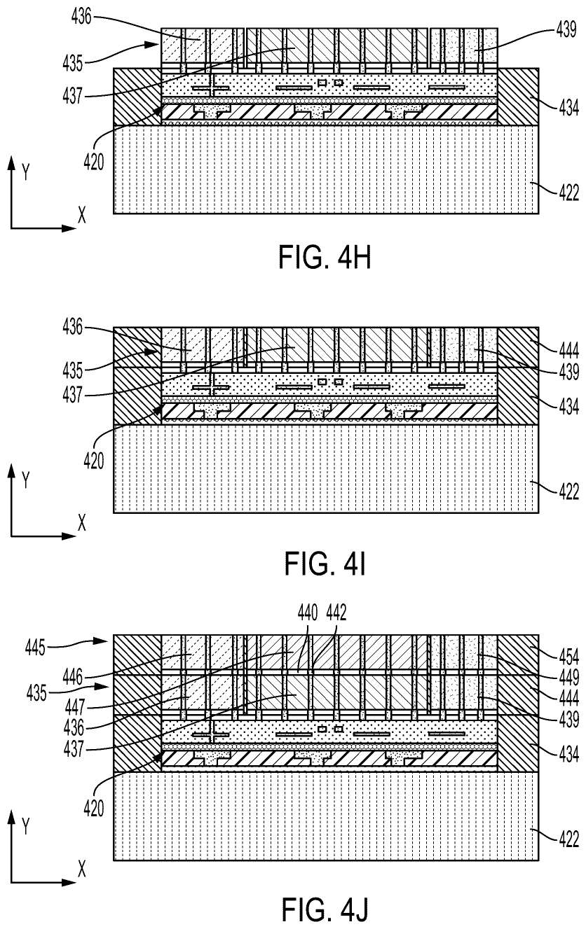

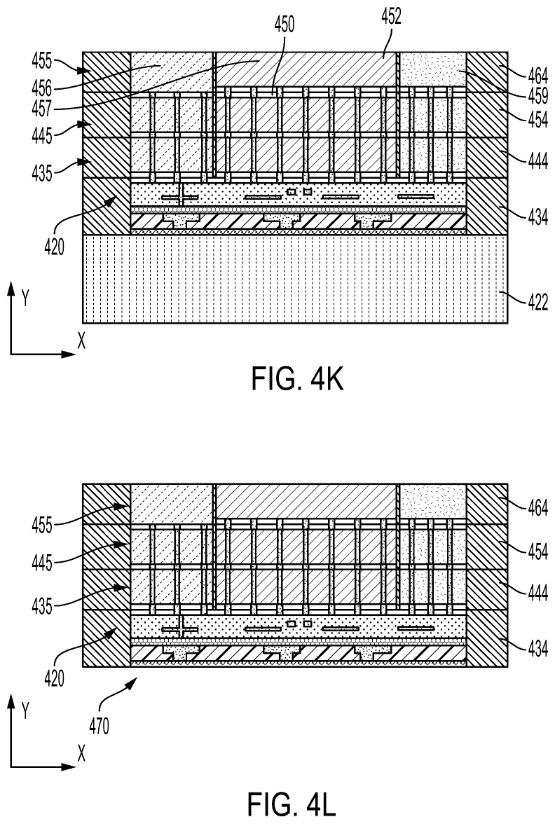

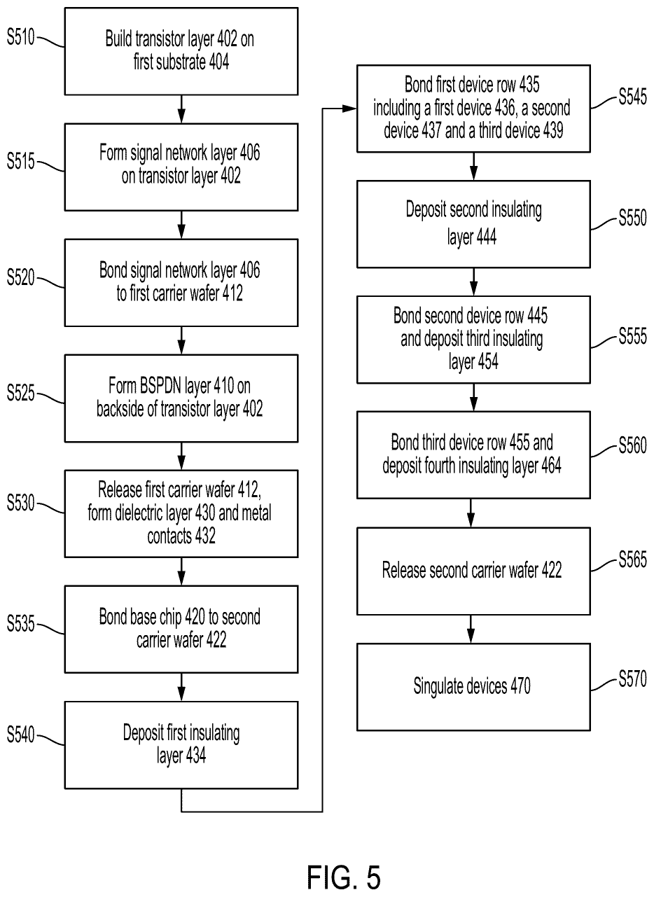

FIGS. 4A-4M depict an illustrative embodiment of the packaging process of a stack assembly 400. FIG. 5 depicts an example embodiment of a process 500 for forming a stack corresponding to the illustrative embodiment of FIGS. 4A-4M. The stack assembly 400 may take the form of the package architecture 100.

FIG. 4A depicts at S510 in FIG. 5 where a transistor layer 402 is formed on a first substrate 404. In some embodiments, the transistor layer 402 may be the transistor layer 154. The transistor layer 402 may be formed using complementary metal-oxide-semiconductor (CMOS) processes, such as depositing, lithography, etching, passivation, etc. In some embodiments, the first substrate 404 may be a silicon wafer, while in other embodiments, the first substrate 404 may include other semiconductor materials such as germanium, or may take the form of other substrates such as an organic substrate or even a SOI substrate such as glass. In some embodiments, the first substrate may be a sacrificial substrate. The transistor layer 402 and structures built directly on the transistor layer 402 may be referred to as front-side layers.

FIG. 4B depicts at S515 in FIG. 5 the formation of a signal network layer 406 on the transistor layer 402. In some embodiments, the signal network layer 405 may be the signal network layer 152. The signal network layer 406 may be formed using CMOS processes to build the various conductive, dielectric and insulative portions of the signal network layer 406 directly on to the transistor layer 402. Alternatively, in some embodiments, the signal network layer 406 may be fully formed and bonded directly to the transistor layer 402.

FIG. 4C depicts at S520 in FIG. 5 a first carrier wafer 412 bonded to the signal network layer 406. The first substrate 404 may then be fully or partially removed, with FIG. 4C showing a remaining portion of the first substrate 404, also referred herein as a remaining substrate layer, present on the transistor layer 402. The first substrate 404 may be fully or partially removed using a variety of processes, including or more grinding, polishing, etching, and peeling processes, including chemical mechanical polishing (CMP). Any remaining portion of the first substrate 404 (e.g., as shown in FIG. 4C) may be planarized to provide a flat surface suitable for additional CMOS processing. The first carrier wafer 412 may be bonded, for example, using an adhesive layer to direct bond to the signal network layer 406. In some embodiments, the first carrier wafer 412 may serve as a carrier wafer, and may be suitable for uses in temperatures up to a threshold temperature. In some embodiments, a threshold temperature may be about 400° C., while in other embodiments the threshold temperature may be larger or smaller.

FIG. 4D depicts at S525 in FIG. 5 where a BSPDN layer 410 is formed on the backside of the transistor layer 402. In some embodiments, the BSPDN layer 410 is formed using CMOS processing. The BSPDN layer 410 may be formed by building directly on the backside of the transistor layer 402 by depositing additional materials on the remaining substrate layer, or may be formed in the first substrate 404 by conducting patterning steps such as lithography and etching to build trenches, vias, and holes within the remaining substrate layer. In some embodiments, the BSPDN layer 410 may be formed by both building directly on the first substrate 404 and conducting patterning steps to build within the first substrate 404. In some embodiments, multiple power layers may be formed with each layer stacking on the previous layer. In some embodiments, the BSPDN layer 410 may be produced on a separate substrate and transferred to the backside of the transistor layer 402. In some embodiments, the BSPDN layer 410 may be provided as a multi-layer structure. In some embodiments, the BSPDN layer 410 may be provided as the aforementioned BSPDN layer 158. In some embodiments, the BSPDN layer 410, the transistor layer 402 and the signal network layer 406 may together form a base chip 420, which may be substantially similar to the base chip 104 in FIG. 1A and FIG. 1B.

FIG. 4E depicts at S530 in FIG. 5 where the first carrier wafer 412 may be debonded from the base chip 420, which may be, for example, by using one or more of layer release, chemical release, thermal release, or photo release techniques to release an adhesive layer coupling the first carrier wafer 412 to the base chip 420. Additionally, on top of the base chip 420, a first dielectric layer 430 and a first conductive layer 432 are formed using CMOS processing steps. The CMOS processing steps may include deposition, etching, patterning, lithography, and any other suitable steps. The first dielectric layer 430 may contact directly the signal network layer 406, and the first conductive layer 432 may form a redistribution layer including pads, via, and other forms of suitable interconnections for additional mounting. In some embodiments, a portion of the surface of the first conductive layer 432 may be patterned so as to expose an exposed portion of the first conductive layer 432.

FIG. 4F depicts at S535 in FIG. 5 where the base chip 420 is bonded to a second carrier wafer 422. The second carrier wafer 422 may be a silicon wafer, glass substrate, or any other form of substrate appropriate for processing conditions. The second carrier wafer 422 may, in some embodiments, have a release layer deposited on the surface of the second carrier wafer 422 prior to bonding of the base chip 420. The base chip 420 may be bonded such that the BSPDN layer 410 is in contact with the second carrier wafer 422, or in contact with the release layer. In some embodiments, the second carrier wafer 422 may be bonded to the base chip 420 at S535 prior to the debonding of the first carrier wafer 412 at S530.

FIG. 4G depicts at S540 in FIG. 5 a first insulating layer 434 is deposited over the second carrier wafer 422. The first insulating layer 434 may be thick enough to extend the vertical height of the base chip 420. In some embodiments, the first insulating layer 434 may cover the first dielectric layer 430, and some or all of the first insulating layer 434 may be removed from a surface of the first dielectric layer 430, for example by patterning, grinding, etching, and other forms of CMOS processing.

FIG. 4H depicts at S545 in FIG. 5 the mounting of a first device row 435 on the surface of the first dielectric layer 430 and the first conductive layer 432. The first device row 435 includes a first device 436, a second device 437 and a third device 439, which may be memory devices or core processing dies, and other forms of chiplets and circuits as described herein. The first device row 435 is bonded to the base chip 420 via a hybrid bonding process. In the hybrid bonding process, the first dielectric layer 430 bonds via fusion bonding to corresponding dielectric components within the first device 436, the second device 437 and third device 439, while the first conductive layer 432 provides a metallic bond between the conductive material of the first conductive layer 432 and the corresponding pads, vias and other metallic contacts of the first device row 435. A thermal process or heat treatment may use heat in the hybrid bonding process to allow dielectric and/or conductive portions to bond. One or more of the devices of the first device row 435 may have a TSV or other form of via extending vertically along the entire height of the first device row 435. The vias may be formed prior to the placement of the devices, after the placement of the devices in the first device row 435, or in some combination thereof.

FIG. 4I depicts at S550 in FIG. 5 a second insulating layer 444 is deposited over the first insulating layer 434. The second insulating layer 444 may be substantially the same thickness as the first device row 435. In some embodiments, the second insulating layer 444 may cover the first device row 435, and some or all of the second insulating layer 444 may be removed from covering the first device row 435, for example by patterning, grinding, etching, and other forms of CMOS processing.

FIG. 4J depicts at S555 in FIG. 5 the processes for a second device row 445, with a second dielectric layer 440 and a second conductive layer 442 deposited on the first device row 435. The second dielectric layer 440 and the second conductive layer 442 may be subjected to CMOS processing steps to create an interconnection for the second device row 445 to be mounted thereon, with a fourth device 446, a fifth device 447 and sixth device 449 mounted and coupled to the first device row 435. The devices of the second device row 445 may be memory devices or core processing dies, and other forms of chiplets and circuits as described herein. One or more of the devices of the second device row 445 may have a TSV or other form of via extending vertically along the entire height of the second device row 445. The vias may be formed prior to the placement of the devices, after the placement of the devices in the second device row 445, or in some combination thereof.

In some embodiments, the second device row 445 may be bonded to the first device row 435 via a hybrid bonding process (e.g., where the second dielectric layer 440 bonds via fusion bonding to corresponding dielectric components within the fourth device 446, the fifth device 447 and sixth device 449, while the second conductive layer 442 provides a metallic bond between the conductive material of the second conductive layer 442 and the corresponding pads, vias and other metallic contacts of the second device row 445). A thermal process or heat treatment may use heat in the hybrid bonding process to allow dielectric and/or conductive portions to bond. A third insulating layer 454 may be deposited over the second insulating layer 444. In some embodiments, the third insulating layer 454 may have substantially the same thickness as the second device row 445. In some embodiments, the third insulating layer 454 may cover the second device row 445, and some or all of the third insulating layer 454 may be removed from a surface of the second device row 445, for example by patterning, grinding, etching, and other forms of CMOS processing.

FIG. 4K depicts at S560 in FIG. 5 the processes for a third device row 455, which are substantially similar to the processes at S555, with a third dielectric layer 450 and a third conductive layer 452 deposited on the second device row 445. The third dielectric layer 450 and the third conductive layer 452 may be subjected to CMOS processing steps to create an interconnection for the third device row 455 to be mounted thereon, with a seventh device 456, an eighth device 457 and ninth device 459 mounted and coupled to the first device row 435. The devices of the third device row 455 may be memory devices or core processing dies, and other forms of chiplets and circuits as described herein. One or more of the devices of the third device row 455 may have a TSV or other form of via extending vertically along the entire height of the third device row 455. The vias may be formed prior to the placement of the devices, after the placement of the devices in the third device row 455, or in some combination thereof.

The third device row 455 may be bonded to the second device row 445 via a hybrid bonding process where the third dielectric layer 450 bonds via fusion bonding to corresponding dielectric components within the seventh device 456, the eighth device 457 and ninth device 459, while the third conductive layer 452 provides a metallic bond between the conductive material of the third conductive layer 452 and the corresponding pads, vias and other metallic contacts of the third device row 455. A thermal process or heat treatment may use heat in the hybrid bonding process to allow dielectric and/or conductive portions to bond. A fourth insulating layer 464 may be deposited over the third insulating layer 454. In some embodiments, the fourth insulating layer 464 may have substantially the same thickness as the third device row 455. In some embodiments, the fourth insulating layer 464 may cover the third device row 455, and some or all of the fourth insulating layer 464 may be removed from covering the third device row 455, for example by patterning, grinding, etching, and other forms of CMOS processing.

FIG. 4L depicts at S565 in FIG. 5 the release (or debonding) of the second carrier wafer 422 from the base chip 420. The second carrier wafer 422 may be debonded, for example, by using one or more of layer release, chemical release, thermal release, or photo release techniques to release an adhesive layer coupling the second carrier wafer 422 to the BSPDN layer 410. For example, in some embodiments a chemical release technique may use a solvent to dissolve the adhesive directly, while a thermal release technique may apply heat to the carrier wafer to melt the adhesive, and a photo release technique may use lasers to directly apply energy to the adhesive layer to reduce the adhesive strength.

FIG. 4L also depicts at S570 in FIG. 5 where an individual device 470 may be separated and removed from a larger set of devices. For example, the previous steps may have taken place using a combination of front end of line, FEOL, and back end of line, BEOL, processes with a plurality of devices being assembled on shared carrier wafers. After the individual devices are completed, the devices may then be singulated into individual devices. The processes used for singulation may vary, and may include physical dicing, laser dicing, scribe and break, and dice before grind processes. Any other appropriate method may be used.

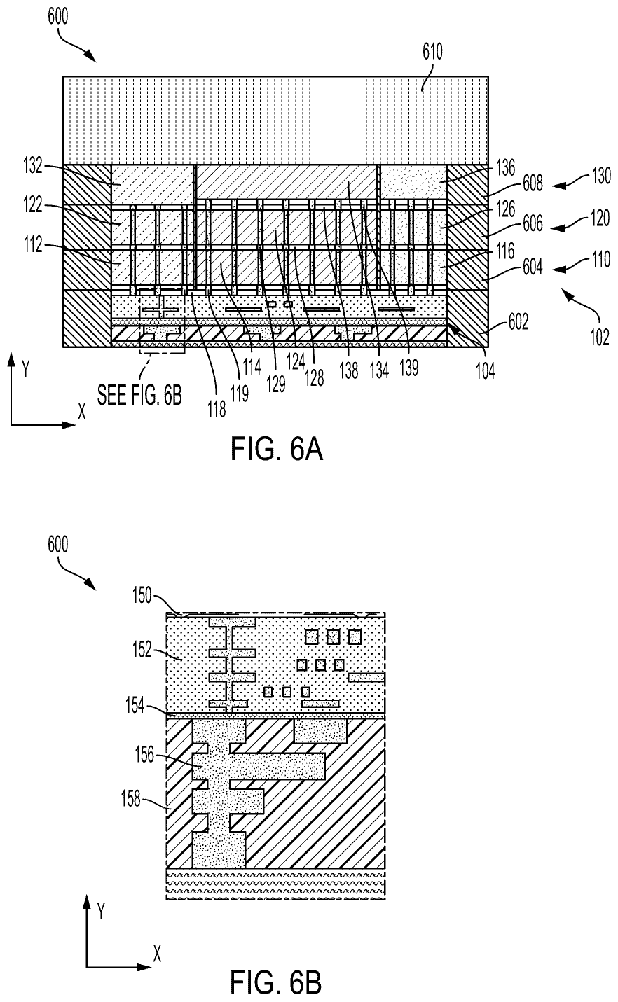

FIG. 6A and FIG. 6B depict an exemplary embodiment of a package architecture 600 which includes additional structural support compared to the package architecture 100. The package architecture 600 includes the elements of package architecture 100 of FIG. 1A and FIG. 1B and includes a set of insulating layers and a structural dummy layer 610. The set of insulating layers includes a first insulating layer 434, a second insulating layer 444, a third insulating layer 454 and a fourth insulating layer 464, although the number of insulating layers may vary. The first insulating layer 602 may be co-planar and substantially the same thickness as the base chip 104. The first insulating layer 602 may contact a supporting substrate, if provided for the base chip 104. The second insulating layer 604 may be mounted on the first insulating layer 602, and be substantially coplanar with and the substantially the same thickness as the first stack layer 110. The third insulating layer 606 may be mounted on the second insulating layer 604 and be substantially coplanar with and the substantially the same thickness as the second stack layer 120. The fourth insulating layer 608 may be mounted on the third insulating layer 606, and be substantially coplanar with and the substantially the same thickness as the third stack layer 130. The structural dummy layer 610 may be mounted above the third stack layer 130 and the fourth insulating layer 608. In some embodiments, the structural dummy layer 610 may be a dielectric material, and may be fusion bonded to the fourth insulating layer 608. A thermal process or heat treatment may use heat in the hybrid bonding process to allow dielectric and/or conductive portions to bond. In other embodiments, the structural dummy layer 610 may be, for example, a layer of silicon and may be held in place, for example, using an adhesive such as a resin or epoxy to hold the structural dummy layer in place. In some embodiments, the structural dummy layer 610 and the insulating layers may provide mechanical support and stability for the devices of the package architecture 600. In some embodiments, the structural dummy layer 610 and the insulating layers may provide thermodynamic support and stability for the devices of the package architecture 600, for example, by providing a thermal pathway for heat to flow from the stack of devices to a cooling surface on the structural dummy layer 610.

In some embodiments, the devices used within the stacks described above may be selected from known good die and chiplets. In some embodiments, the selection of known good dies may be used to increase the yield of the process. In some embodiments, the base chips may be selected from known good chips or known good die.

In some embodiments, the package architecture proposed herein may deliver a stacked package architecture by stacking known good die and chiplets (i.e., DRAM, processors, ASICs) onto known good logic die using hybrid bonding for meeting increasing demands of computing of chips for AI, high-performance computing (HPC) and data centers. The package architecture proposed herein may provide a configurable stack on logic die to bring in flexibility for computing and matching, for example, core count, capacity, and bandwidth for mix and match.

While this specification may contain many specific implementation details, the implementation details should not be construed as limitations on the scope of any claimed subject matter, but rather be construed as descriptions of features specific to particular embodiments. Certain features that are described in this specification in the context of separate embodiments may also be implemented in combination in a single embodiment. Conversely, various features that are described in the context of a single embodiment may also be implemented in multiple embodiments separately or in any suitable subcombination. Moreover, although features may be described above as acting in certain combinations and even initially claimed as such, one or more features from a claimed combination may in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

Thus, particular embodiments of the subject matter have been described herein. Other embodiments are within the scope of the following claims. In some cases, the actions set forth in the claims may be performed in a different order and still achieve desirable results. Additionally, the processes depicted in the accompanying figures do not necessarily require the particular order shown, or sequential order, to achieve desirable results. In certain implementations, multitasking and parallel processing may be advantageous.

As will be recognized by those skilled in the art, the innovative concepts described herein may be modified and varied over a wide range of applications. Accordingly, the scope of claimed subject matter should not be limited to any of the specific exemplary teachings discussed above, but is instead defined by the following claims.

What is claimed is:

1. A device comprising:
a first layer including at least one transistor;
a second layer on a first side of the first layer, the second layer including a signal layer; a third layer on a second side of the first layer, the second side opposite the first side, the third layer including a power layer; and
a stack coupled to the second layer, the stack including a first device row and a second device row, wherein each of the first device row and the second device row includes at least one device, and wherein the second device row is mounted on the first device row; and
wherein the devices of the first device row differ from the devices of the second device row.

2. The device of claim 1, wherein the first device row includes a processing device.

3. The device of claim 1, wherein the second device row includes a memory device.

4. The device of claim 3, wherein the memory device is mounted on top of a processing device.

5. The device of claim 3 wherein the memory device is mounted on top of a device other than a processing device.

6. The device of claim 3, wherein the memory device is a dynamic random access memory device.

7. The device of claim 1, wherein the first device row includes at least one device.

8. The device of claim 1, wherein the first device row includes a device other than a memory device or a processing device.

9. The device of claim 1, wherein the stack is mounted on the signal layer.

10. A system comprising:
a substrate, the substrate including a logic layer;
a first layer, the first layer including a first device row, the first layer over the substrate;
a second layer, the second layer including a second device row, wherein the second layer is arranged over the first layer, and wherein the second device row is coupled to the first device row; and
a third layer, the third layer including a third device row, wherein the third layer is arranged over the second layer, and wherein the third device row is coupled to the second device row,
wherein each of the first device row, the second device row and the third device row includes at least one device, and
wherein the device composition of the first device row differs from the second device row.

11. The system of claim 10, wherein the device composition of the third device row is substantially the same as the second device row.

12. The system of claim 10, wherein the substrate includes a power layer and a signal layer, wherein the power layer is coupled to the logic layer, and wherein the logic layer is coupled to the signal layer.

13. The system of claim 12, wherein the power layer and the signal layer are coupled to the first layer.

14. The system of claim 10, wherein the first device row includes a processing device.

15. The system of claim 10, wherein the second device row includes a memory device.

16. A method comprising:
forming a transistor layer on a first side of a first substrate, the transistor layer including at least one transistor;
forming a signal layer on the transistor layer, the signal layer communicatively coupled to the transistor layer;
forming a power layer on a second side of the first substrate, the second side opposite the first side, the power layer electrically coupled to the transistor layer;
bonding a first device row to the signal layer; and
bonding a second device row to the first device row.

17. The method of claim 16, wherein bonding the first device row to the signal layer includes depositing a dielectric layer, patterning a via in the dielectric layer, and heating the first device row and the signal layer together to bond between the first device row and the signal layer.

18. The method of claim 16, wherein the device composition of the second device row differs from the first device row.

19. The method of claim 16, further comprising bonding a third device row to the second device row, the device composition of the third device row substantially the same as the second device row.

20. The method of claim 16,
wherein forming the signal layer on the transistor layer includes forming a redistribution layer on a surface of the signal layer, and
wherein bonding the first device row to the signal layer includes depositing a first dielectric layer over the redistribution layer, and patterning the first dielectric layer to expose an exposed portion of redistribution layer, and mounting conductive contacts of the first device row on the exposed portion of the redistribution layer, and performing a thermal process to bond the exposed portion of the redistribution layer to the conductive contacts of the first device row.
